(19) United States
(12) Patent Application Publication
(10) Pub. No.: US 2024/0332452 A1
(43) Pub. Date: Oct. 3, 2024

(54) LIGHT-EMITTING SUBSTRATE AND MANUFACTURING METHOD THEREOF, BACKLIGHT MODULE AND DISPLAY APPARATUS

(71) Applicants: Hefei BOE Ruisheng Technology Co., Ltd., Anhui (CN); BOE TECHNOLOGY GROUP CO., LTD., Beijing (CN)

(72) Inventors: Xiaolin GENG, Beijing (CN); Hai TANG, Beijing (CN); Xing LIU, Beijing (CN); Liang GAO, Beijing (CN); Ming ZHAI, Beijing (CN)

(73) Assignees: Hefei BOE Ruisheng Technology Co., Ltd., Anhui (CN); BOE TECHNOLOGY GROUP CO., LTD., Beijing (CN)

(21) Appl. No.: 18/639,410

(22) Filed: Apr. 18, 2024

Related U.S. Application Data
(63) Continuation of application No. PCT/CN2023/085258, filed on Mar. 30, 2023.

(51) Int. Cl. H01L 33/10; G02F 1/13357; H01L 25/075; H01L 33/54

(52) U.S. Cl. CPC H01L 33/10; G02F 1/133603; H01L 25/0753; H01L 33/54; H01L 2933/005

(57) ABSTRACT

A light-emitting substrate includes: a substrate having a first surface; a plurality of light-emitting devices located on the first surface; a reflective layer located on the first surface, the reflective layer having a plurality of first openings, a light-emitting device being located in a first opening; a plurality of dam structures located on the reflective layer, each dam structure having a second opening, an orthogonal projection of a first opening on the substrate being located within an orthogonal projection of the second opening on the substrate; and a plurality of first encapsulation structures located on a side of the plurality of light-emitting devices away from the substrate, a first encapsulation structure covering at least one light-emitting device, the orthogonal projection of the second opening on the substrate being located within an orthographic projection of the first encapsulation structure on the substrate.

### CROSS-REFERENCE TO RELATED APPLICATION

This application is a Bypass Continuation Application of International Patent Application No. PCT/CN2023/085258, filed on Mar. 30, 2023, which is incorporated herein by reference in its entirety.

### TECHNICAL FIELD

The present disclosure relates to the field of display technologies, and in particular, to a light-emitting substrate, a manufacturing method of a light-emitting substrate, a backlight module and a display apparatus.

### BACKGROUND

Liquid crystal display (LCD) apparatuses are more and more widely used due to their advantages such as low power consumption, miniaturization, light weight and small thickness. For example, they has been used in various fields such as mobile phones, flat panel displays, vehicles, televisions, and public displays.

### SUMMARY

In an aspect, a light-emitting substrate is provided, including: a substrate, a plurality of light-emitting devices, a reflective layer, dam structures and a plurality of first encapsulation structures. The substrate has a first surface. The plurality of light-emitting devices are located on the first surface. The reflective layer is located on the first surface. The reflective layer has a plurality of first openings, and a light-emitting device is located in a first opening. The plurality of dam structures are located on the reflective layer. Each dam structure has a second opening. An orthogonal projection of the first opening on the substrate is located within an orthogonal projection of the second opening on the substrate. The plurality of first encapsulation structures are located on a side of the plurality of light-emitting devices away from the substrate. A first encapsulation structure covers at least one light-emitting device. The orthogonal projection of the second opening on the substrate is located within an orthographic projection of the first encapsulation structure on the substrate.

In some embodiments, the dam structure has an inner side wall close to the first opening. The inner side wall of the dam structure and a side wall of the first opening have a distance therebetween.

In some embodiments, an orthographic projection of the dam structure on the substrate and the orthographic projection of the first encapsulation structure on the substrate have an overlapping region.

In some embodiments, the overlapping region is an annular pattern, and a radial size of the annular pattern is in a range of 0.05 mm to 0.1 mm.

In some embodiments, a ratio γ of a size of the second opening to a size of the first encapsulation structure satisfies: 0.92≤γ≤0.96.

In some embodiments, a shape of an orthographic projection of the dam structure on the substrate is annular. The annular shape includes an inner contour and an outer contour; the inner contour is closer to the light-emitting device than the outer contour; and the inner contour constitutes a boundary of the orthogonal projection of the second opening on the substrate.

In some embodiments, a distance between the inner contour and the outer contour is in a range of 1.0 mm to 1.2 mm.

In some embodiments, a shape of the outer contour is a central symmetric pattern or an axial symmetric pattern.

In some embodiments, the outer contour is in a shape of a rectangle or a rounded rectangle.

In some embodiments, at least two of the dam structures are connected to each other to form a one-piece structure.

In some embodiments, the plurality of dam structures are connected to each other to form a grid-like structure; and the second opening is a square of the grid-like structure.

In some embodiments, a thickness of the dam structure is in a range of 0.03 mm to 0.05 mm.

In some embodiments, a material of the dam structure includes white glue, and a reflectivity of the dam structure is greater than or equal to 90%.

In some embodiments, a distance between the first opening and the light-emitting device located in the first opening is in a range of 0.1 mm to 0.2 mm.

In some embodiments, the light-emitting substrate further includes a plurality of driver chips located on the first surface. A driver chip is electrically connected to at least one light-emitting device, and the driver chip is configured to drive the at least one light-emitting device to emit light. The reflective layer covers the plurality of driver chips.

In some embodiments, the light-emitting substrate further includes a plurality of second encapsulation structures. An orthographic projection of the driver chip on the substrate is located within an orthographic projection of a second encapsulation structure on the substrate.

In some embodiments, the plurality of second encapsulation structures and the plurality of dam structures are arranged in the same layer and made of the same material.

In another aspect, a manufacturing method of a light-emitting substrate is provided. The manufacturing method includes: providing a substrate, the substrate having a first surface; fixing a plurality of light-emitting devices to the first surface; forming a reflective layer on the first surface, the reflective layer having a plurality of first openings, a light-emitting device being located in a first opening; forming a plurality of first encapsulation structures on the plurality of light-emitting devices, a first encapsulation structure covering at least one light-emitting device; and forming a plurality of dam structures on the reflective layer, each dam structure having a second opening, an orthogonal projection of the first opening on the substrate being located within an orthogonal projection of the second opening on the substrate, the orthogonal projection of the second opening on the substrate being located within an orthographic projection of the first encapsulation structure on the substrate.

In some embodiments, before forming the plurality of dam structures on the reflective layer, the manufacturing method further includes: fixing a plurality of driver chips to the first surface. A driver chip is electrically connected to at least one light-emitting device, and the driver chip is configured to drive the at least one light-emitting device to emit light. During a process of forming the reflective layer on the first surface using a printing process, the reflective layer further covers the plurality of driver chips.

In some embodiments, the manufacturing method further includes: forming a plurality of second encapsulation structures on the plurality of driver chips, an orthographic projection of the driver chip on the substrate being located within an orthographic projection of a second encapsulation structure on the substrate.

In yet another aspect, a backlight module is provided, including: the light-emitting substrate as described in any one of the above embodiments, and an optical film located on a light exit side of the light-emitting substrate.

In yet another aspect, a display apparatus is provided, including: the backlight module as described in the above embodiments; a color filter substrate located on a light exit side of the backlight module; and an array substrate located between the backlight module and the color filter substrate.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on an actual size of a product, an actual process of a method and an actual timing of a signal involved in the embodiments of the present disclosure.

FIG. 1 is a structural diagram of a display apparatus, in accordance with some embodiments of the present disclosure;

FIG. 2A is a structural diagram of another display apparatus, in accordance with some embodiments of the present disclosure;

FIG. 2B is a schematic diagram of yet another display apparatus, in accordance with some embodiments of the present disclosure;

FIG. 3 is a structural diagram of a backlight module, in accordance with some embodiments of the present disclosure;

FIG. 4 is a structural diagram of a light-emitting substrate, in accordance with some embodiments of the present disclosure;

FIG. 5A is a structural diagram of a light-emitting substrate, in accordance with an implementation manner;

FIG. 5B is a structural diagram of a light-emitting substrate, in accordance with another implementation manner;

FIG. 6 is a structural diagram of another light-emitting substrate, in accordance with some embodiments of the present disclosure;

FIG. 7 is a structural diagram of the light-emitting substrate in FIG. 6 taken along the line AA′;

FIG. 8 is a structural diagram of a first encapsulation structure and a dam structure, in accordance with some embodiments of the present disclosure;

FIG. 9 is a structural diagram of a first encapsulation structure and a dam structure, in accordance with some other embodiments of the present disclosure;

FIG. 10 is a structural diagram of yet another light-emitting substrate, in accordance with some embodiments of the present disclosure;

FIG. 11 is a structural diagram of yet another light-emitting substrate, in accordance with some embodiments of the present disclosure;

FIG. 12 is a diagram showing a process of manufacturing a light-emitting substrate, in accordance with some embodiments of the present disclosure;

FIGS. 13 to 17 are diagrams showing structures of a light-emitting substrate in different manufacturing phases, in accordance with some embodiments of the present disclosure; and

FIGS. 18 and 19 are diagrams showing structures of a light-emitting substrate in different manufacturing phases, in accordance with some other embodiments of the present disclosure.

### DETAILED DESCRIPTION

The technical solutions in some embodiments of the present disclosure will be described clearly and completely with reference to the accompanying drawings. However, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, features defined with “first” and “second” may explicitly or implicitly include one or more of the features. In the description of the embodiments of the present disclosure, the terms “a plurality of” “the plurality of” and “multiple” each mean two or more unless otherwise specified.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

The term such as “about”, “substantially” or “approximately” as used herein includes a stated value and an average value within an acceptable range of deviation of a particular value determined by a person of ordinary skilled in the art, considering measurement in question and errors associated with measurement of a particular quantity (i.e., limitations of a measurement system).

The term such as “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “perpendicular” includes absolute perpendicularity and approximate perpendicularity, and an acceptable range of deviation of the approximate perpendicularity may also be, for example, a deviation within 5°. The term “equal” includes absolute equality and approximate equality, and an acceptable range of deviation of approximate equality may be, for example, that a difference between two equals is less than or equal to 5% of any one of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

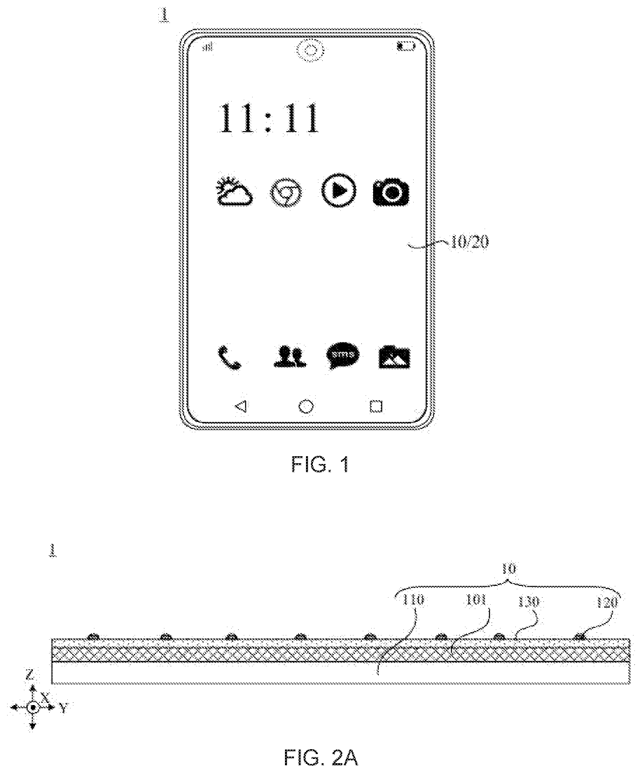

Some embodiments of the present disclosure provide a display apparatus. As shown in FIG. 1, the display apparatus 1 may be any apparatus that displays images whether in motion (e.g., videos) or stationary (e.g., still images), and whether textual or graphical. More specifically, it is expected that the display apparatus in the embodiments may be implemented in or associated with a plurality of electronic devices. The plurality of electronic devices may include (but is not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (such as odometer displays, etc.), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry) etc.

For example, in a case where the display apparatus 1 is a large-sized display apparatus, the display apparatus 1 may include a plurality of display sub-apparatuses, and the plurality of display sub-apparatuses are spliced together to form the large-size display apparatus, so as to satisfy large-size display. This display apparatus may be called a spliced display apparatus.

For example, the display apparatus 1 includes a frame, a display driver integrated circuit (IC), and other electronic components.

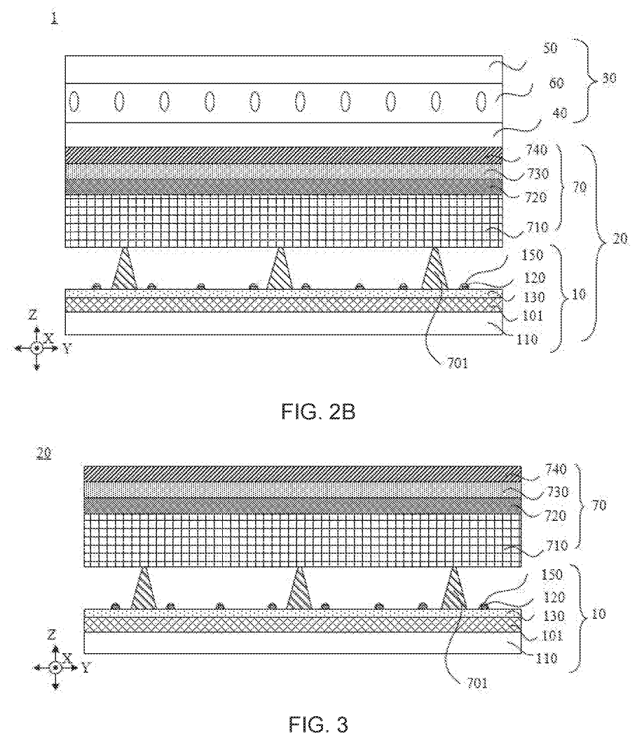

In some embodiments, as shown in FIG. 2A, the display apparatus 1 further includes a light-emitting substrate 10. The light-emitting substrate 10 may be used directly for image display. In this case, the display apparatus 1 is an active light-emitting display apparatus. Since the light-emitting substrate 10 can emit light by itself, there is no need to provide an additional backlight module.

In some other embodiments, as shown in FIG. 2B, the display apparatus 1 may be a liquid crystal display (LCD) apparatus. In this case, for example, the display apparatus 1 further includes a backlight module 20 and a display panel 30.

For example, the display panel 30 includes: an array substrate 40 and a color filter substrate 50. The color filter substrate 50 is disposed on a light-exit side of the backlight module 20. The array substrate 40 is located between the color filter substrate 50 and the backlight module 20.

For example, the backlight module 20 may be used as a light source for providing backlight for the display panel 30. For example, the backlight provided by the backlight module 20 may be white light or blue light. The light-exit side of the backlight module 20 refers to a side where the backlight module 20 emits light.

For example, the array substrate 40 may include a plurality of pixel driving circuits and a plurality of pixel electrodes. For example, the plurality of pixel driving circuits may be arranged in an array. The plurality of pixel driving circuits are electrically connected to the plurality of pixel electrodes in a one-to-one correspondence, and the pixel driving circuit provides a pixel voltage for a corresponding pixel electrode.

For example, the color filter substrate 50 may include a plurality of color filters. For example, when the backlight provided by the backlight module 20 is white light, the color filters may include red filters, green filters and blue filters. For example, the red filter can only transmit red light in incident light, the green filter can only transmit green light in the incident light, and the blue filter can only transmit blue light in the incident light. As another example, when the backlight provided by the backlight module 20 is blue light, the color filters may include red filters and green filters.

For example, the display panel 30 further includes a common electrode. The common electrode may receive a common voltage.

For example, the common electrode may be disposed on the array substrate 40.

As another example, the common electrode may be disposed on the color filter substrate 50.

In some examples, as shown in FIG. 2B, the display panel 30 further includes: a liquid crystal layer 60 located between the color filter substrate 50 and the array substrate 40.

For example, the liquid crystal layer 60 includes a plurality of liquid crystal molecules. For example, an electric field may be created between the pixel electrode and the common electrode due to the action of the pixel voltage and the common voltage, and liquid crystal molecules in the liquid crystal layer 60 located between the pixel electrode and the common electrode may be deflected due to the action of the electric field.

It can be understood that the backlight provided by the backlight module 20 can pass through the array substrate 40 and be incident on the liquid crystal molecules of the liquid crystal layer 60. The liquid crystal molecules are deflected due to the action of the electric field generated between the pixel electrode and the common electrode, thereby changing the amount of light passing through the liquid crystal molecules, so that the light passing through the liquid crystal molecules reaches a preset brightness. The light passes through the filters of different colors in the color filter substrate 50 and then exits. The emitted light includes light of various colors, such as red light, green light, blue light, etc. The light of various colors cooperate with each other to enable the display of the display apparatus 1.

For example, the backlight module 20 may be a direct type backlight module.

In some embodiments, as shown in FIG. 2B, the backlight module 20 further includes a light-emitting substrate 10 and an optical film 70 located on a light-exit side of the light-emitting substrate 10.

It can be understood that Z in FIG. 3 represents a third direction Z, and the third direction Z is a thickness direction of the display apparatus 1.

For example, the optical film 70 includes a diffuser plate 710, a quantum dot film 720, a diffuser sheet 730 and a composite film 740 that are disposed on the light-exit side of the light-emitting substrate 10 in sequence.

For example, the diffusion plate 710 and the diffusion sheet 730 are used to eliminate lamp shadows and uniformize the light emitted by the light-emitting substrate 10 to improve the uniformity of the light.

For example, the quantum dot film 720 is used to convert light emitted by the light-emitting substrate 10. Optionally, when the light emitted by the light-emitting substrate 10 is blue light, the quantum dot film 720 can convert the blue light into white light and improve the purity of the white light.

For example, the composite film 740 is used to increase brightness of the light emitted by the light-emitting substrate 10.

It can be understood that the light emitted by the light-emitting substrate 10 is incident on the optical film 70, the brightness of light is enhanced after emitted from the optical film 70, and the emitted light has high purity and good uniformity.

The backlight module 20 may include a plurality of light-emitting substrates 10 and corresponding optical films. The plurality of light-emitting substrates 10 may be spliced together, and the corresponding optical films are also spliced together, so that the backlight module 20 has a larger size. At this time, the backlight module 20 may be called a spliced backlight module, which may be applied to the spliced display apparatus.

In some examples, as shown in FIG. 2B, the backlight module 20 further includes: support columns 701 disposed between the light-emitting substrate 10 and the diffusion plate 710 of the optical film 70.

For example, the support columns 701 may be fixed on the light-emitting substrate 10 by adhesive. The support columns 701 may also be arranged on the light-emitting substrate 10 by riveting. The support columns 701 are used to support the optical film 70 and make the light emitted by the light-emitting substrate 10 have a certain light-mixing distance, so as to further eliminate lamp shadows and improve the uniformity of light.

In some examples, the light-emitting substrate 10 includes: a substrate 110 and a plurality of light-emitting devices 120. The light-emitting devices 120 may serve as a light source of the light-emitting substrate 10.

For example, the substrate 110 may be a flexible substrate. The flexible substrate may be, for example, a polyethylene terephthalate (PET) substrate, a polyethylene naphthalate (PEN) substrate, or a polyimide (PI) substrate.

For example, the substrate 110 may be a rigid substrate. For example, the substrate 1 may be made of glass. The substrate 110 may also be a printed circuit board (PCB), an aluminum substrate, etc.

For the convenience of description, the substrate 110 is made of glass as an example for description below.

For example, the substrate 110 is a flat plate, and the substrate 110 has a first surface. The plurality of light-emitting devices 120 are located on the first surface.

In some examples, the plurality of light-emitting devices 120 may be mini LEDs, or LEDs, or micro LEDs.

For example, the plurality of light-emitting devices 120 may be arranged in an array, light-emitting devices 120 in each row are arranged in a second direction Y, and light-emitting devices 120 in each column are arranged in a first direction X.

For example, any row of light-emitting devices 120 includes multiple light-emitting devices 120 arranged at intervals in the first direction X, and any column of light-emitting devices 120 includes multiple light-emitting devices 120 arranged at intervals in the second direction Y.

For example, an angle between the first direction X and the second direction Y is 85°, 90°, 95°, etc. This present disclosure takes the angle between the first direction X and the second direction Y as 90° as an example for illustration.

It can be understood that the structure of the light-emitting substrate varies, which may be set according to actual needs. In the present disclosure, the structure of the light-emitting substrate 10 is described by taking an example in which the light-emitting substrate 10 is used to form the backlight module 20.

In some examples, as shown in FIGS. 2B and 3, the light-emitting substrate 10 further includes a reflective layer 130 located on the first surface.

For example, the reflective layer 130 has a plurality of first openings 131.

For example, the plurality of first openings 131 of the reflective layer 130 are used to expose surfaces of conductive patterns (such as end portions of signal lines) located on the substrate 110 or an alignment mark and substrate number mentioned below, to avoid being covered by the reflective layer 130; and the conductive pattern whose surface is exposed is used to realize electrical connection with an electronic component (such as a light-emitting device 120).

In some examples, a material of the reflective layer 130 includes white oil. The reflectivity of white oil to light is about 90%. In this way, the reflective layer 130 can reflect more light, thereby achieving good light utilization effect. In addition, the reflective layer 130 may also protect the light-emitting substrate 10 to prevent the light-emitting substrate 10 from being corroded by water and oxygen and to avoid scratching damage, etc.

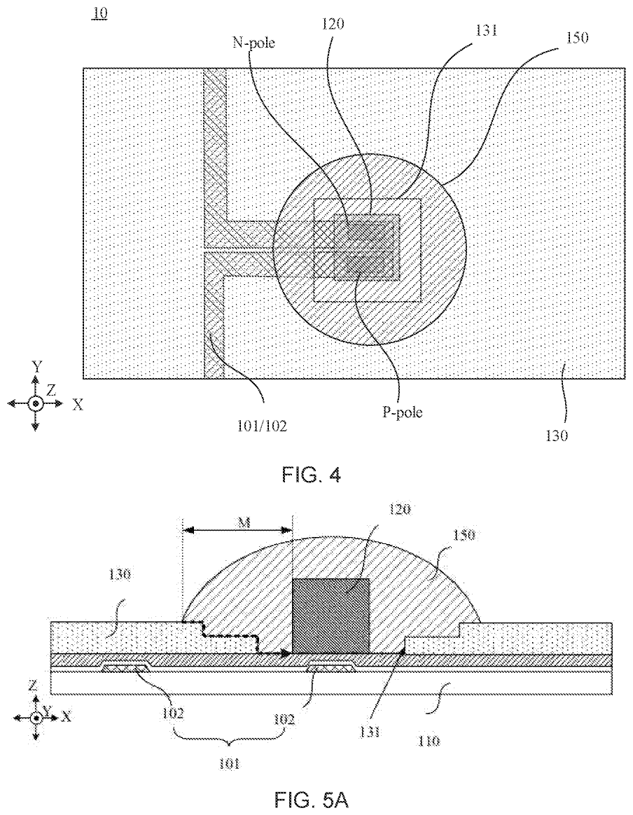

For example, as shown in FIGS. 4 and 6, a light-emitting device 120 is located in a first opening 131.

For example, the plurality of first openings 131 and the plurality of light-emitting devices 120 may be arranged in one-to-one correspondence.

For example, the light-emitting substrate 10 further includes: an alignment mark (Mark) and a substrate number (Panel ID) disposed on the substrate 110.

For example, the alignment mark is used to realize the installation alignment between the light-emitting substrate 10 and the optical film 70. The substrate number is used to label and identify a single light-emitting substrate 10. Therefore, the alignment mark and the substrate number should not be covered by the reflective layer 130 to facilitate alignment or identification.

In some examples, as shown in FIG. 3, the light-emitting substrate 10 further includes: a circuit structure layer 101 located between the substrate 110 and the reflective layer 130.

For example, as shown in FIG. 4, the plurality of light-emitting devices 120 are electrically connected to the circuit structure layer 101.

For example, the circuit structure layer 101 includes signal lines 102. An N-pole and a P-pole of the light-emitting device 120 are electrically connected to different signal lines 102, and the signal lines 102 may provide the light-emitting device 120 with required electrical signals.

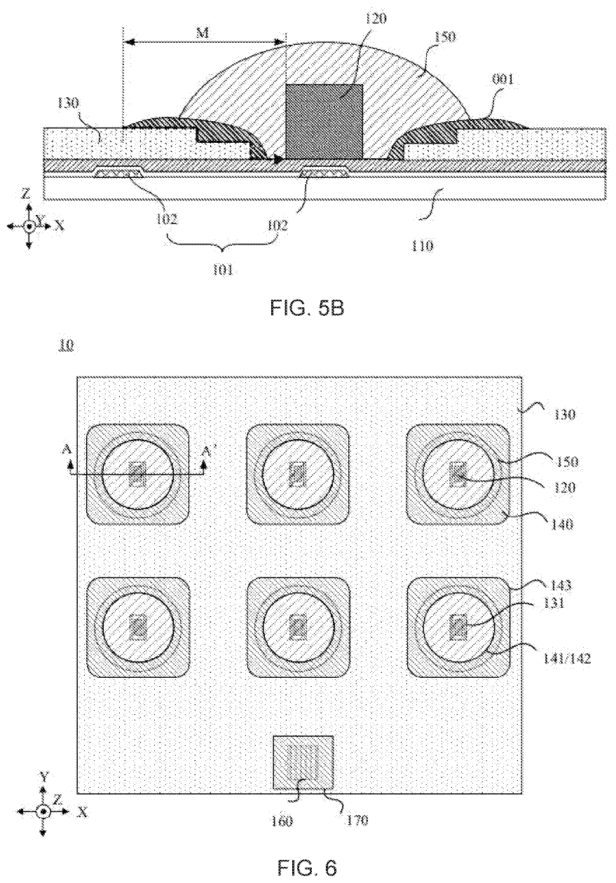

In some examples, as shown in FIG. 5A, the light-emitting substrate 10 further includes a plurality of first encapsulation structures 150 disposed on a side of the plurality of light-emitting devices 120 away from the substrate 110.

For example, a first encapsulation structure 150 covers at least one light-emitting device 120.

For example, as shown in FIG. 4, one first encapsulation structure 150 covers one light-emitting device 120.

As another example, one first encapsulation structure 150 covers a plurality of light-emitting devices 120.

For the convenience of introduction, one first encapsulation structure 150 covers one light-emitting device 120 as an example for description below.

For example, as shown in FIGS. 4, 5A and 5B, the first encapsulation structure 150 covers the first opening 131, the light-emitting device 120 located in the first opening 131 and a part of the reflective layer 130.

Based on this, since the first encapsulation structure 150 can be used to protect the light-emitting device 120, it can prevent water, oxygen, etc. from intruding into the interior of the light-emitting device 120 and in turn avoid corrosion of the light-emitting device 120 which affects light-emitting and life of the light-emitting device 120, and it can prevent water, oxygen, etc. from intruding into the signal lines in the circuit structure layer 101 and in turn avoid corrosion of the signal lines which affects light-emitting of the light-emitting device 120.

For example, the first encapsulation structure 150 is made of a light-transmissive material, and the light emitted by the light-emitting device 120 can be emitted by passing through the first encapsulation structure 150. The first encapsulation structure can be used to modulate the light emission shape of the light-emitting device 120.

It can be understood that the anti-water and anti-oxygen ability of the light-emitting substrate 10 seriously affects the yield of the light-emitting substrate. The inventors have explored the water and oxygen intrusion path in the light-emitting substrate and have found that water and oxygen mainly invaded into the interior of the light-emitting device 120 along the surface of the reflective layer 130 away from the substrate toward the first opening 131 (the location of the dotted line with an arrow in FIG. 5A illustrates the water and oxygen intrusion path), thus eroding the signal line(s) 102 and the light-emitting device(s) 120. In an implementation, in the light-emitting substrate as shown in FIG. 5A, a plurality of first encapsulation structures 150 are arranged on the side of the light-emitting devices away from the substrate, so that the first encapsulation structures 150 can be used to encapsulate and protect the light-emitting devices 120. In this implementation, the anti-water and anti-oxygen distance M of the light-emitting substrate is approximately in a range of 1.0 mm to 1.1 mm. Since the light-emitting substrate is designed to be anti-water and anti-oxygen using the first encapsulation structures 150, the anti-water and anti-oxygen distance M here refers to a distance between boundaries of orthographic projections, on the substrate, of the first encapsulation structure and the light-emitting device. The inventors have also conducted a water and oxygen resistance test on the light-emitting substrate and have found that in a high-temperature and high-humidity environment, the light-emitting devices and signal lines are easily corroded by water and oxygen within a relatively short period of time. As a result, a single light-emitting device or multiple light-emitting devices in the light-emitting substrate may have undesirable phenomena such as low light-emitting brightness or even no light, and the light-emitting substrate has poor anti-water and anti-oxygen ability.

In another implementation, in order to improve the anti-water and anti-oxygen ability of the light-emitting substrate, as shown in FIG. 5B, before forming the first encapsulation structures 150 on the light-emitting substrate, white glue 001 is arranged between the first encapsulation structures 150 and the reflective layer 130, so that the first encapsulation structures 150 and the white glue 001 can be used together to encapsulate and protect the light-emitting devices. In this implementation, the anti-water and anti-oxygen distance M of the light-emitting substrate is approximately in a range of 1.3 mm to 1.5 mm, and the increase in the anti-water and anti-oxygen distance of the light-emitting substrate is limited. Since the light-emitting substrate is designed to be anti-water and anti-oxygen using the first encapsulation structures 150 and the white glue 001, the anti-water and anti-oxygen distance M here refers to a distance between an outer boundary of an orthographic projection of white glue 001 on the substrate and the boundary of the orthographic projection of the light-emitting device on the substrate. The inventors have conducted a water and oxygen resistance test on the light-emitting substrate 10 and have found that in a high-temperature and high-humidity environment, the anti-water and anti-oxygen ability of the light-emitting substrate is improved to a certain extent.

The location of the dotted line with an arrow in FIG. 5B illustrates the water and oxygen intrusion path.

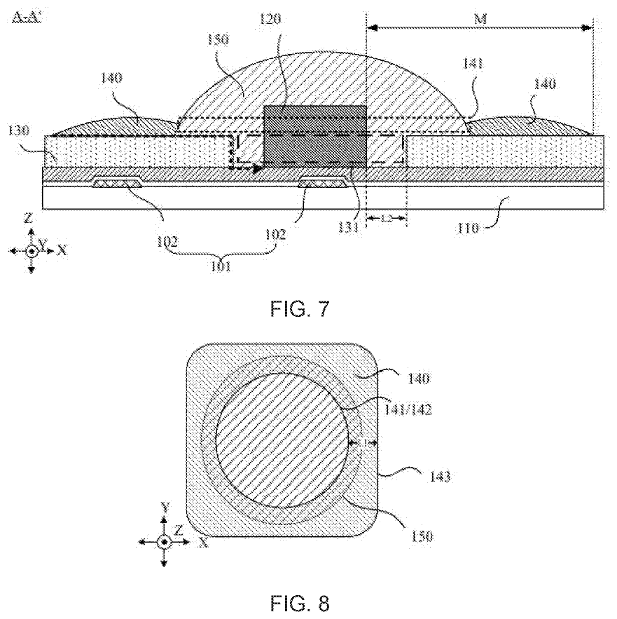

In order to further improve the anti-water and anti-oxygen ability of the light-emitting substrate 10, some embodiments of the present disclosure provide another light-emitting substrate, as shown in FIGS. 6 and 7, the light-emitting substrate 10 includes the substrate 110, the light-emitting devices 120, the reflective layer 130 and the plurality of first encapsulation structures 150 in the above embodiments, and further includes: a plurality of dam structures 140 located on the reflective layer 130.

In some examples, each dam structure 140 has a second opening 141, and an orthogonal projection of a first opening 131 on the substrate 110 is located within an orthogonal projection of a second opening 141 on the substrate 110.

For example, the second opening 141 of the dam structure 140 exposes a portion of the reflective layer 130.

For example, the plurality of first openings 131 are in one-to-one correspondence with the plurality of second openings 141. Since the plurality of first openings 131 and the plurality of light-emitting devices 120 are in one-to-one correspondence, the plurality of second openings 141 and the plurality of light-emitting devices 120 are also in one-to-one correspondence. A light-emitting device 120 is located in a second opening 141, and a dam structure 140 surrounds a light-emitting device 120.

For example, in a direction perpendicular to the substrate 110, a center of the first opening 131 coincides with a center of the second opening 141. An area of the orthogonal projection of the first opening 131 on the substrate 110 is less than an area of the orthogonal projection of the second opening 141 on the substrate 110.

For example, for a first opening 131 and a second opening 141 where the same light-emitting device 120 is located, a side wall of the first opening 131 and the light-emitting device 120 have a smaller distance therebetween.

In some examples, the orthogonal projection of a second opening 141 on the substrate 110 is located within an orthographic projection of a first encapsulation structure 150 on the substrate 110.

For example, a boundary of the orthogonal projection of the second opening 141 on the substrate 110 is located within a boundary of the orthographic projection of a first encapsulation structure 150 on the substrate 110.

For example, an edge of the dam structure 140 close to the light-emitting device 120 surrounded by the dam structure 140 overlaps the corresponding first encapsulation structure 150.

For example, the dam structure 140 has the ability to block the penetration of water and oxygen.

In this way, the dam structures 140 and the first encapsulation structures 150 may be combined to protect the light-emitting devices 120 and the signal lines 102 electrically connected to the light-emitting devices 120, and the dam structures 140 can be used to increase the anti-water and anti-oxygen distances of the light-emitting substrate 10, thereby further enhancing the corrosion resistance of the light-emitting substrate 10, and in turn improving the luminous life of the light-emitting devices 120 and the light-emitting substrate 10.

As for the structural features of the substrate 110, light-emitting device 120 and reflective layer 130 in the light-emitting substrate in the embodiments, reference can be made to the description of the above-mentioned embodiments, and details will not be repeated here.

In the light-emitting substrate 10 provided in the embodiments of the present disclosure, a plurality of dam structures 140 are arranged on the reflective layer 130, each dam structure 140 has a second opening 141, and an orthogonal projection of each first opening 131 in the reflective layer 130 on the substrate 110 is located within an orthogonal projection of a second opening 141 on the substrate 110; and a plurality of first encapsulation structures 150 are provided, a first encapsulation structure 150 covers at least one light-emitting device 120, and an orthogonal projection of a second opening 141 on the substrate is located within an orthographic projection of a first encapsulation structure 150 on the substrate 110. Therefore, in the light-emitting substrate 10, the first encapsulation structures 150 protect the light-emitting devices 120 and the signal lines 102 from water and oxygen. Moreover, the dam structures 140 are used to further increase the anti-water and anti-oxygen distances of the light-emitting substrate 10. As a result, it is possible to enhance the anti-water and anti-oxygen ability and corrosion resistance of the light-emitting substrate 10, and in turn improve the luminous life of the light-emitting devices 120 and the light-emitting substrate 10. As shown in FIG. 7, the anti-water and anti-oxygen distance M of the light-emitting substrate 10 in the embodiments of the present disclosure may be in a range of 2.0 mm to 2.3 mm, which greatly improves the anti-water and anti-oxygen ability and corrosion resistance of the light-emitting substrate 10.

The location of the dotted line with an arrow in FIG. 7 illustrates the water and oxygen intrusion path. The anti-water and anti-oxygen distance M in FIG. 7 refers to a distance between an outer contour of the orthographic projection of the dam structure 140 on the substrate 110 and a boundary of the orthographic projection of the light-emitting device 120 on the substrate 110.

In some embodiments, as shown in FIG. 7, the dam structure 140 has an inner side wall close to the first opening 131. There is a distance between the inner side wall of the dam structure 140 and a side wall of the first opening 131.

For example, the inner side wall of the dam structure 140 constitutes a side wall of the second opening 141.

For example, the distance between the inner side wall of the dam structure 140 surrounding the light-emitting device 120 and the light-emitting device 120 is greater than the distance between the side wall of the first opening 131 and the light-emitting device 120.

For example, the boundary of the orthogonal projection of the second opening 141 on the substrate 110 does not overlap with the boundary of the orthogonal projection of the first opening 131 on the substrate 110. The boundary of the orthogonal projection of the first opening 131 on the substrate 110 is located within the boundary of the orthogonal projection of the second opening 141 on the substrate 110.

For example, a part of the reflective layer 130 exists between each dam structure 140 and the substrate 110, and each dam structure 140 is not in direct contact with the substrate 110.

In this way, it may be possible to improve the light extraction efficiency of the light-emitting device 120 and the light-emitting substrate 10, avoid that the orthogonal projection of the first opening 131 on the substrate 110 coincides with the orthogonal projection of the second opening 141 on the substrate 110, and avoid a large area of the part of the dam structure 140 overlapping the first encapsulation structure 150. Therefore, it prevents the light emitted by the light-emitting device 120 in the first opening 131 from being blocked by the dam structure 140 in the process of exiting from the first encapsulation structure 150, and in turn avoids the loss of the light emitted by the light-emitting device 120 due to the absorption by the dam structure 140.

In some embodiments, the orthographic projection of the dam structure 140 on the substrate 110 and the orthographic projection of the first encapsulation structure 150 on the substrate 110 have an overlapping region.

For example, a part of the boundary of the orthographic projection of the dam structure 140 on the substrate 110 is located within the boundary of the orthographic projection of the first encapsulation structure 150 on the substrate 110.

In this way, the dam structure 140 may encapsulate the edge of the first encapsulation structure 150, and the dam structure 140 may increase the anti-water and anti-oxygen distance, thereby improving the anti-water and anti-oxygen ability and corrosion resistance of the light-emitting substrate 10, and improving the lifetime of the light-emitting device 120 and the light-emitting substrate 10. In addition, it may be possible to avoid the edge warping of the first encapsulation structure 150, prevent external water and oxygen from intruding into the light-emitting device and signal line(s) from the edge of the first encapsulation structure 150, prevent external water and oxygen from corroding the light-emitting devices and signal lines, and in turn to avoid affecting the light emission of the light-emitting device 120.

It can be understood that an outer boundary of the overlapping region is composed of the boundary of the orthographic projection of the first encapsulation structure 150 on the substrate 110, and an inner boundary of the overlapping region is composed of the boundary of the orthogonal projection of the second opening 141 of the dam structure 140 on the substrate 110. Therefore, the shape of the overlapping region is determined by the shape of the first encapsulation structure 150 and the shape of the second opening 141. The shape of the overlapping region varies, which may be set according to actual situations and is not limited in the embodiments of the present disclosure.

In some embodiments, as shown in FIG. 6, the overlapping region is an annular pattern, and a radial size of the annular pattern is in a range of 0.05 mm to 0.1 mm.

For example, the outer boundary of the overlapping region is a first circle, and the inner boundary of the overlapping region is a second circle; a center of the first circle substantially coincides with a center of the second circle; and a difference between a radius of the first circle and a radius of the second circle is in a range of 0.05 mm to 0.1 mm.

For example, the radial size of the annular pattern may be 0.05 mm, 0.07 mm, 0.08 mm, 0.09 mm, or 0.1 mm.

Since the overlapping region is set as the annular pattern, an outer edge of the first encapsulation structure 150 may be covered by a part of the dam structure 140. In this way, the dam structure 140 and the first encapsulation structure 150 may be combined to increase the anti-water and anti-oxygen distance of the light-emitting substrate 10, thus improving the anti-water and anti-oxygen ability of the light-emitting substrate 10. In addition, by setting the radial size of the annular pattern within the above range, not only can it improve the light extraction efficiency of the light-emitting device 120, avoid the influence of the dam structure 140 located on the first encapsulation structure 150 on the light emission of the light-emitting device 120, but it can also avoid the area of the overlapping region being too small to effectively improve the anti-water and anti-oxygen ability of the dam structure 140.

In some embodiments, a ratio γ of the size of the second opening 141 to the size of the first encapsulation structure 150 is in an inclusive range of 0.92 to 0.96 (0.92≤γ≤0.96).

It can be understood that the shape of the orthographic projection of the first encapsulation structure 150 on the substrate 110 varies, which may be set according to actual situations. The shape of the orthogonal projection of the second opening 141 on the substrate 110 varies, which may be set according to actual situations. The shape of the orthographic projection of the first encapsulation structure 150 on the substrate 110 and the shape of the orthogonal projection of the second opening 141 on the substrate 110 may be the same or different.

For example, the size of the second opening 141 refers to the size of the orthogonal projection of the second opening 141 on the substrate 110. The size of the first encapsulation structure 150 refers to the size of the orthographic projection of the first encapsulation structure 150 on the substrate 110. Hereinafter, the size of the second opening 141 is taken as an example for description.

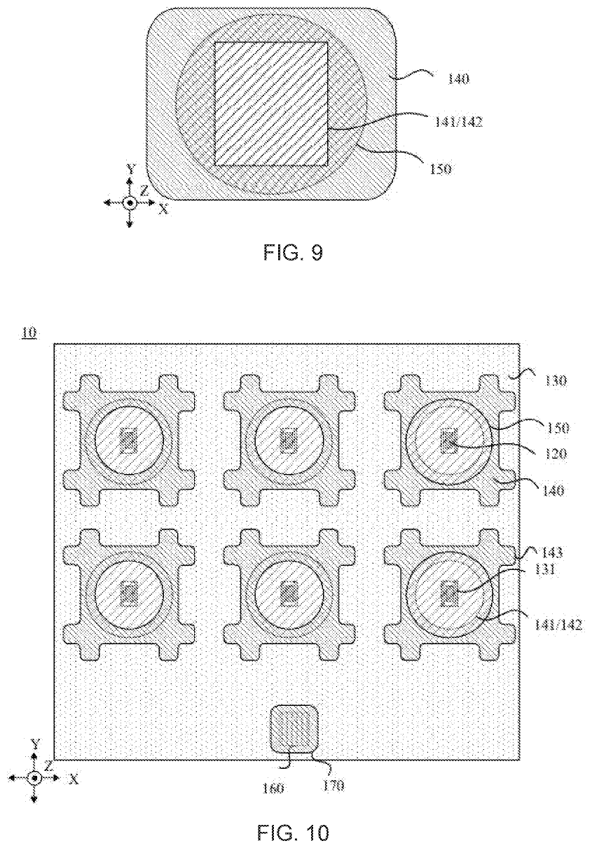

For example, as shown in FIG. 8, when the orthogonal projection of the second opening 141 on the substrate 110 is in a shape of a circle, the size of the second opening 141 refers to the radius of the circle. When the orthogonal projection of the second opening 141 on the substrate 110 is in a shape of an ellipse, the size of the second opening 141 refers to half of the size of the major axis of the ellipse. As shown in FIG. 9, when the orthogonal projection of the second opening 141 on the substrate 110 is in a shape of a rectangle, the size of the second opening 141 refers to half of the size of the diagonal of the rectangle. When the orthogonal projection of the second opening 141 on the substrate 110 is in a shape of a regular polygon, the size of the second opening 141 refers to half of the size of the diagonal of the regular polygon.

Similarly, as shown in FIG. 8, when the orthographic projection of the first encapsulation structure 150 on the substrate 110 is in a shape of a circle, the size of the first encapsulation structure 150 refers to the radius of the circle. As for other situations, reference may be made to the size of the second opening 141 as described above, and details will not be repeated here.

For example, the ratio γ of the size of the second opening 141 to the size of the first encapsulation structure 150 may be 0.92, 0.93, 0.94, 0.95, or 0.96.

In this way, the size of the first encapsulation structure 150 is greater than the size of the second opening 141, thereby ensuring that a part of the dam structure 140 overlaps the corresponding first encapsulation structure 150. As a result, it may be possible to improve the anti-water and anti-oxygen ability and corrosion resistance of the light-emitting substrate 10 and improve the luminous life of the light-emitting devices 120 and the light-emitting substrate 10.

In some embodiments, as shown in FIGS. 6 and 8, the shape of the orthographic projection of the dam structure 140 on the substrate 110 is annular. The annular shape includes an inner contour 142 and an outer contour 143. The inner contour 142 is located inside the outer contour 143, and is closer to the light-emitting device 120 than the outer contour 143. The inner contour 142 constitutes the boundary of the orthogonal projection of the second opening 141 on the substrate 110.

For example, as shown in FIG. 8, the inner contour 142 is in a shape of a circle.

As another example, as shown in FIG. 9, the inner contour 142 is in a shape of a rectangle.

In this way, the dam structure 140 can surround the light-emitting device 120, thereby increasing the anti-water and anti-oxygen distance at each position along the periphery of the light-emitting device 120, and in turn improving the anti-water and anti-oxygen ability of the light-emitting substrate 10.

In some embodiments, as shown in FIG. 8, a distance L1 between the inner contour 142 and the outer contour 143 is in a range of 1.0 mm to 1.2 mm.

For example, the distance between the inner contour 142 and the outer contour 143 is 1.0 mm, 1.05 mm, 1.10 mm, 1.17 mm or 1.2 mm.

In this way, it may be possible to ensure that the dam structure 140 can overlap the first encapsulation structure 150 and can prevent external water and oxygen from intruding from the edge of the first encapsulation structure 150 to the light-emitting device 120 and signal line(s), and in turn improve the corrosion resistance of the light-emitting substrate 10.

In some embodiments, as shown in FIGS. 8 to 10, the shape of the outer contour 143 is a central symmetric pattern or an axial symmetric pattern.

In this way, it may facilitate the fabricating of the dam structures 140, and may also ensure that portions of the dam structure 140 arranged on two opposite sides of the light-emitting device 120 in the first direction X have approximately the same shape and approximately the same area. When the light emitted by the light-emitting device 120 is projected onto the two portions of the dam structure, it may be possible to ensure that the two portions of the dam structure have approximately the same reflective area and approximately the same reflectivity, and in turn ensure the uniformity of the light emitted by the light-emitting substrate 10 to a certain extent.

It can be understood that the central symmetric pattern or axial symmetric pattern may be of various types, such as circle and rhombus, which may be set according to actual needs, and the embodiments of the present disclosure are not limited thereto.

In some embodiments, the outer contour 143 is in a shape of a rectangle or a rounded rectangle.

In this way, it is conducive to simplifying the manufacturing process of the dam structures 140.

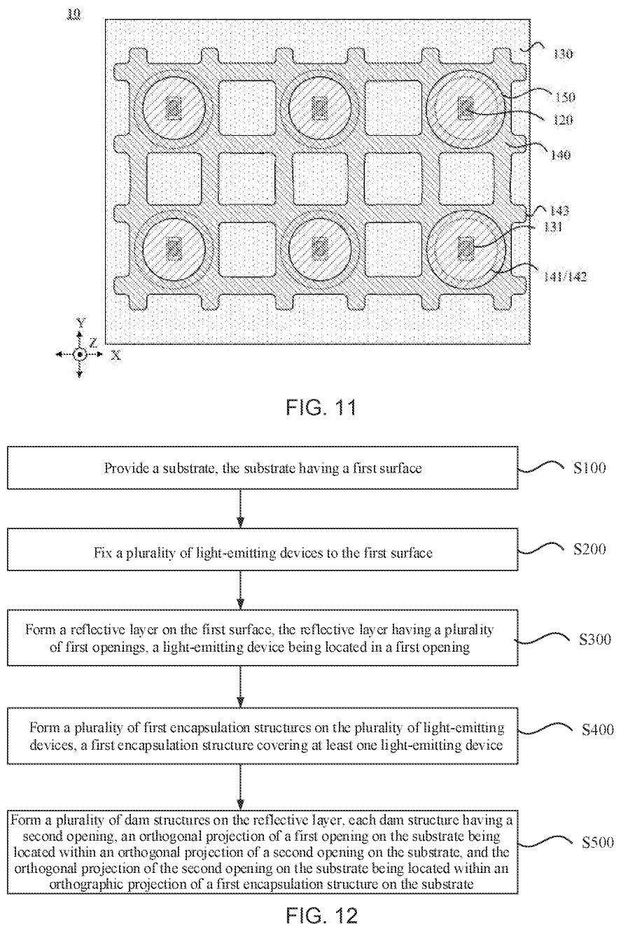

In some embodiments, as shown in FIG. 11, at least two dam structures 140 are connected to each other to be of a one-piece structure.

For example, two dam structures 140 are connected to each other to form a one-piece structure.

As another example, a plurality of dam structures 140 are connected to each other to form a one-piece structure.

Therefore, at least two dam structures 140 can be formed in a single manufacturing process, which is conducive to simplifying the manufacturing process of the dam structures 140 and the light-emitting substrate 10.

In some embodiments, as shown in FIG. 11, the plurality of dam structures 140 connected to each other are of a grid-like structure. The second openings 141 are squares of the grid-like structure.

Therefore, it may be possible to increase an area of the dam structures 140 covering the reflective layer, and in turn enhance the anti-water and anti-oxygen ability and corrosion resistance of the light-emitting substrate 10.

In some embodiments, a thickness of the dam structure 140 is in a range of 0.03 mm to 0.05 mm.

For example, the thickness of the dam structure 140 is 0.03 mm, 0.035 mm, 0.04 mm, 0.045 mm, or 0.05 mm.

In this way, the auxiliary encapsulation effect of the dam structure 140 may be ensured, and the anti-water and anti-oxygen ability and corrosion resistance of the light-emitting substrate 10 may be enhanced.

In some embodiments, the dam structures 140 are made of white glue, and the reflectivity of the dam structures 140 is greater than or equal to 90%.

For example, the reflectivity of the dam structures 140 is 90%, 92%, 95%, 97%, or 99%.

In this way, the dam structure 140 may reflect light incident on its surface, so as to avoid the shielding of the reflective layer by the dam structures 140 which affects the light extraction efficiency of the light-emitting substrate 10.

In some embodiments, as shown in FIG. 7, a distance L2 between the first opening 131 and the light-emitting device 120 located in the first opening 131 is in a range of 0.1 mm to 0.2 mm.

For example, the distance L2 between the first opening 131 and the light-emitting device 120 located in the first opening 131 may be 0.1 mm, 0.12 mm, 0.15 mm, 0.17 mm or 0.2 mm.

In this way, the distance between the reflective layer 130 and the light-emitting device 120 may be small, which reduces the loss caused by the light emitted by the light-emitting device being incident on the gap between the side wall of the first opening 131 and the corresponding light-emitting device 120, thereby improving the light extraction efficiency of the light-emitting device and the light-emitting substrate and ameliorating the light leakage phenomenon of the light-emitting substrate.

In some embodiments, as shown in FIG. 6, the light-emitting substrate 10 further includes a plurality of driver chips 160 located on the first surface. A driver chip 160 is electrically connected to at least one light-emitting device 120, and the driver chip 160 is configured to drive the at least one light-emitting device 120 electrically connected thereto to emit light.

For example, the driver chip 160 may be electrically connected to the light-emitting device(s) 120 through signal line(s) in the circuit structure layer 101.

For example, a single driver chip 160 is electrically connected to a single light-emitting device 120 and drive the light-emitting device 120 to emit light.

For example, a single driver chip 160 is electrically connected to four light-emitting devices 120 and drive the four light-emitting devices 120 to emit light.

For example, a single driver chip 160 is electrically connected to nine light-emitting devices 120 and drive the nine light-emitting devices 120 to emit light.

In some examples, the reflective layer 130 covers the plurality of driver chips 160.

For example, as shown in FIG. 6, orthographic projections of the driver chips 160 on the substrate 110 are located within the orthographic projection of the reflective layer 130 on the substrate 110.

In this way, it may be possible to increase the area proportion of the reflective layer 130 on the substrate 110, increase the reflective area where the light emitted by the light-emitting device 120 is reflected by the reflective layer, and in turn improve the luminance efficiency of the light-emitting substrate 10 and ameliorate the light leakage and other phenomena of the light-emitting substrate 10. In addition, the reflective layer 130 may also play a certain protective role, which prevents external water and oxygen from intruding into the driver chip 160 and corroding the driver chip 160, and avoids affecting the signal transmitted from the driver chip 160 to the light-emitting device 120 which affects the light emission of the light-emitting device 120 and the light-emitting substrate 10.

In some embodiments, as shown in FIG. 6, the light-emitting substrate 10 further includes a plurality of second encapsulation structures 170. An orthographic projection of a driver chip 160 on the substrate 110 is located within an orthographic projection of a second encapsulation structure 170 on the substrate 110.

For example, the plurality of second encapsulation structures 170 are in one-to-one correspondence with the plurality of driver chips 160.

That is, a boundary of the orthographic projection of the driver chip 160 on the substrate 110 is located within a boundary of the orthographic projection of the second encapsulation structure 170 on the substrate 110.

For example, the shape of the orthographic projection of the second encapsulation structure 170 on the substrate 110 varies, which may be set according to actual situations.

For example, as shown in FIGS. 6, 10 and 17, the orthographic projection of the second encapsulation structure 170 on the substrate 110 may be in a shape of a rectangle, a rounded rectangle, or a circle.

In this way, the driver chip 160 and the signal line(s) electrically connected thereto may be further encapsulated and protected by the second encapsulation structure 170, thus avoiding the thickness of the reflective layer being insufficient to completely cover the driver chip 160, preventing water, oxygen, etc. from intruding and corroding the driver chip 160 and the signal line(s), avoiding affecting the operation of the driver chip 160 and the light-emitting device 120, and in turn improving the light extraction efficiency of the light-emitting device 120 and the light-emitting substrate 10.

In some embodiments, the plurality of second encapsulation structures 170 and the plurality of dam structures 140 are arranged in the same layer and made of the same material.

For example, the plurality of second encapsulation structures 170 may be made of white glue.

In this way, the plurality of second encapsulation structures 170 and the plurality of dam structures 140 can be formed in a single manufacturing process, thereby simplifying the manufacturing process of the light-emitting substrate 10.

The light-emitting substrate 10 provided in the above-mentioned embodiments of the present disclosure can be applied to the backlight module and the display apparatus mentioned in the above embodiments. Beneficial effects that can be achieved by the backlight module and the display apparatus provided in some embodiments of the present disclosure are the same as the beneficial effects that can be achieved by the light-emitting substrate 10 provided in some embodiments of the present disclosure, and details will not be repeated here.

In one implementation, for a large-sized light-emitting substrate, the manufacturing method of the light-emitting substrate generally includes the following steps: material preparation→screen printing process to form the reflective layer→automated optical inspection (AOI)→die bonding→dot repair→AOI→encapsulation, etc. In this manufacturing method, the reflective layer has poor dimensional accuracy and poor morphological accuracy, the size of the first opening in the reflective layer fluctuates greatly, and the size of each first opening has poor consistency; and after the die bonding process, the relative position of the first opening and the light-emitting device is prone to offset, which may cause defects such as mura or bright and dark stripes in images displayed by the display apparatus. For a medium-sized and large-sized light-emitting substrate or medium-sized and small-sized light-emitting substrate, the manufacturing method generally includes the following steps: material preparation→screen printing process to form the reflective layer→exposure→development→AOI→die bonding→encapsulation, etc. The reflective layer formed by this manufacturing method has high dimensional accuracy, and the phenomenon that the relative position of the first opening and the light-emitting device is prone to offset is alleviated.

However, in the above two manufacturing methods, the process of forming the reflective layer is before the die bonding (that is, fixing the light-emitting devices). During the process of forming the reflective layer, the material of the reflective layer will produce cured precipitates during a curing process. The cured precipitates will cover the pads to be soldered to the light-emitting devices, thus affecting the subsequent die bonding process, affecting the soldering effect of the light-emitting devices and the pads which results in defects such as virtual soldering, and in turn affecting the die bonding yield of the light-emitting substrate. In addition, since the reflective layer is formed before the die bonding, in order to avoid the influence of the step difference between the reflective layer and the substrate (the step difference is the thickness of the reflective layer, which is about 60 μm) on the die bonding operation, only a small number of light-emitting devices can be fixed at a time during the die bonding operation, resulting in the high cost of the die bonding. Moreover, during the process of fixing the small number of light-emitting devices, the previously formed reflective layer is prone to adhere to other light-emitting devices adjacent to the small number of light-emitting devices, which in turn is prone to a situation of other light-emitting devices being fixed at the same time, resulting in errors in the fixed positions of the light-emitting devices, which leads to the mura phenomenon in the display apparatus.

In light of this, some embodiments of the present disclosure further provide a manufacturing method of a light-emitting substrate, and the manufacturing method is used, for example, to manufacture the light-emitting substrate provided in the above embodiments. As shown in FIG. 12, the manufacturing method includes S100 to S500.

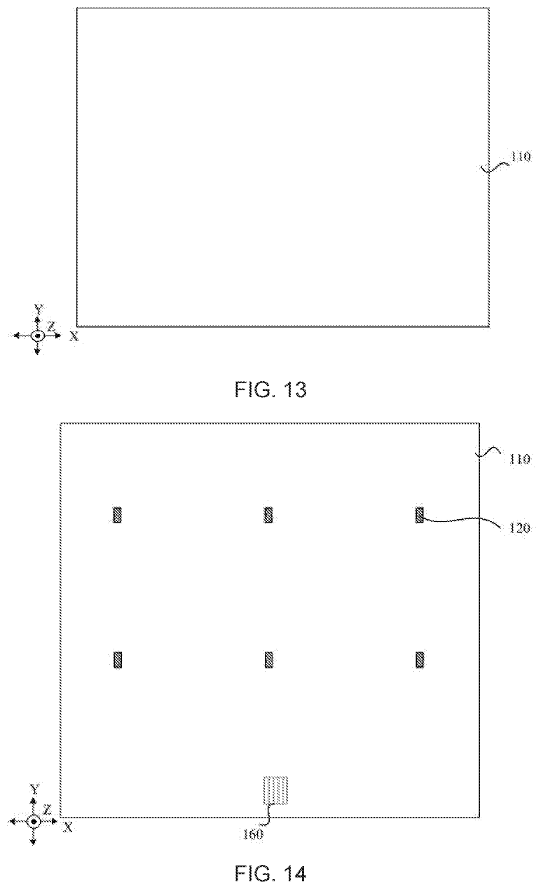

In S100, as shown in FIG. 13, a substrate 110 is provided, and the substrate 110 has a first surface.

For example, the substrate 110 is a flat plate.

As for the introduction to the substrate 110, reference may be made to the introduction in some of the above embodiments of the present disclosure, and details will not be repeated here.

In S200, as shown in FIG. 14, a plurality of light-emitting devices 120 are fixed to the first surface.

For example, corresponding pads are provided at positions where the light-emitting devices 120 are to be fixed to the substrate 110. The process of fixing the light-emitting devices 120 may include, for example: dipping or printing solder and soldering flux onto the pads, then placing the corresponding light-emitting devices 120 on the pads, and then fixing the light-emitting devices 120 to the substrate 110 through a reflow soldering process. The pads are electrically connected to signal lines.

For example, the light-emitting devices 120 are LEDs, micro LEDs, mini LEDs, etc.

For example, the light-emitting devices 120 are mini LEDs, and the structure of the mini LED may be an upright structure, a vertical structure, or an inverted structure.

For example, the plurality of light-emitting devices 120 are evenly distributed on the substrate 110, so that light emitted from the entire surface of the light-emitting substrate 10 is uniform, which improves the display quality of the backlight module 20 and the display apparatus 1.

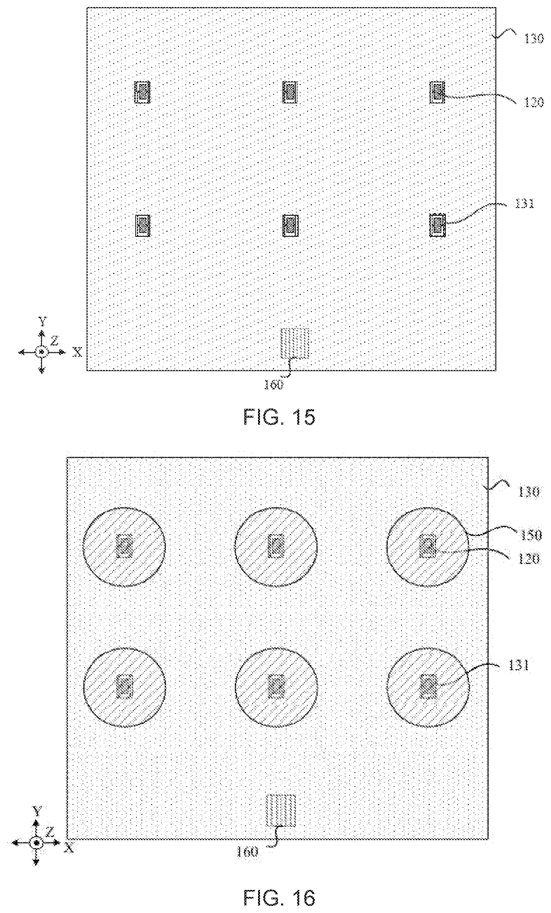

In S300, as shown in FIG. 15, a reflective layer 130 is formed on the first surface. The reflective layer 130 has a plurality of first openings 131, and a light-emitting device 120 is located in a first opening 131.

For example, a thickness of the reflective layer 130 is in a range of 50 μm to 70 μm.

For example, the thickness of the reflective layer 130 may be 50 μm, 55 μm, 60 μm or 70 μm.

In this way, the reflective layer 130 may have a certain thickness to ensure a high reflectivity of the reflective layer 130 and prevent light from being lost through the reflective layer, which is conducive to improving the light extraction efficiency of the light-emitting substrate.

For example, the reflective layer 130 may be made of white oil.

In some examples, the reflective layer 130 is formed on the first surface by using an inkjet printing process or a 3D printing process.

For example, the inkjet printing process includes spraying the material of the reflective layer onto the first surface by a printing nozzle valve to form a reflective film. After a total thickness of a plurality of reflective films formed by repeatedly printing reaches a preset thickness, the reflective films are pre-cured with UV light to form the reflective layer.

For example, the thickness of the reflective film formed by the inkjet printing in a single printing process is in a range of 5 μm to 10 μm, and the viscosity of the material of the reflective layer suitable for the inkjet printing is in a range of 8 mPa·s to 20 mPa·s.

The method of forming the reflective layer using the inkjet printing process may make the formed reflective layer have high dimensional accuracy and morphological accuracy; and the printing speed of inkjet printing is fast, which is conducive to saving the manufacturing cycle of the light-emitting substrate.

For example, the 3D printing process has high flexibility, the printing nozzle outputs the fluid to the substrate 110 to be subjected to the printing in a contactless way, and the reflective layer 130 formed by the printing has high dimensional accuracy and morphology accuracy, so that the distance between the side wall of the first opening and the side wall of the corresponding light-emitting device may be accurately controlled. Therefore, the distance between the side wall of the first opening and the side wall of the corresponding light-emitting device reaches a range of 100 μm to 200 μm, which is conducive to improving the proportion of the area the reflective layer 130 to the area of the substrate 110, and improving the utilization rate of the light emitted by the light-emitting device 120 and the light extraction efficiency of the light-emitting substrate 10.

Moreover, since the reflective layer 130 is formed by the 3D printing process, the relative displacement deviation between the position of the first opening 131 in the reflective layer 130 and the position of the pad that will fix the light-emitting device 120 may be controlled to be within a range of +50 μm. Therefore, it may be possible to avoid a fixed position deviation of the light-emitting device 120 caused by a large relative offset between the first opening 131 and the pad, which affects the light emission uniformity of the light-emitting substrate 10. In addition, the plurality of first openings 131 in the reflective layer 130 may be evenly arranged, thereby further improving the uniformity of light emitted from the light-emitting substrate 10.

In S400, as shown in FIG. 16, a plurality of first encapsulation structures 150 are formed on the plurality of light-emitting devices 120. A first encapsulation structure 150 covers at least one light-emitting device 120.

For example, the first encapsulation structures 150 may be made of a light-transmissive material. For example, a first encapsulation film is formed by spraying a light-transmissive material through a coating process, and the plurality of first encapsulation structures 150 are formed after the first encapsulation film is cured.

For example, the first encapsulation structure 150 may be in a shape of a hemisphere.

For example, an orthographic projection of the first encapsulation structure 150 on the substrate may be in a shape of a circle, and the radius of the circle may be in a range of 2.5 mm±0.1 mm. The height of the first encapsulation structure 150 may be in a range of 0.5 mm±0.1 mm.

For example, the height of the first encapsulation structure 150 is greater than the height of the light-emitting device 120, thereby realizing effective encapsulation and protection against water and oxygen corrosion.

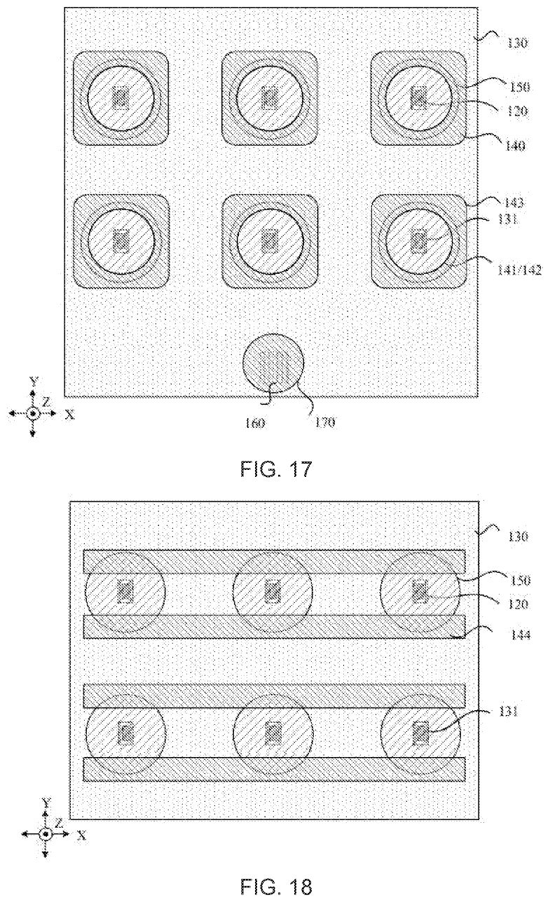

For example, a first encapsulation structure 150 covers multiple light-emitting devices 120, which is conducive to saving the manufacturing cost of the light-emitting substrate and shortening the cycle of manufacturing the light-emitting substrate 10. In S500, as shown in FIG. 17, a plurality of dam structures 140 are formed on the reflective layer 130. Each dam structure 140 has a second opening 141, and an orthogonal projection of a first opening 131 on the substrate 110 is located within an orthogonal projection of a second opening 141 on the substrate 110. The orthogonal projection of a second opening 141 on the substrate 110 is located within an orthographic projection of a first encapsulation structure 150 on the substrate 110.

For example, the dam structures 140 may be made of a white glue material.

For example, the plurality of dam structures 140 are formed on the reflective layer 130 using a coating process or a printing process.

For example, the white glue material is sprayed around the first encapsulation structure 150, and then the white glue material is cured to form the dam structure 140. Alternatively, a printing device may be used to print the white glue material around the first encapsulation structure 150 and on a corresponding portion of the reflective layer, and then the white glue material is cured to form the dam structure 140.

As for the description of the structure of the dam structure, reference can be made to the description in some of the above embodiments in the present disclosure, and details will not be repeated here.

In this way, the plurality of dam structures 140 are formed after the first encapsulation structures 150 have been formed. The overlapping region of the dam structure 140 and the first encapsulation structure 150 may be used to consolidate the encapsulation effect of the first encapsulation structure 150, and increase the anti-water and anti-oxygen distance of the light-emitting substrate. Therefore, it is possible to improve the anti-water and anti-oxygen ability of the light-emitting substrate 10, enhance the corrosion resistance of the light-emitting devices and the signal lines, and improve the luminous lifetime of the light-emitting device 120 and the light-emitting substrate 10.

In the embodiments of the present disclosure, in the manufacturing method of the light-emitting substrate 10, the light-emitting devices 120 are first fixed to the substrate 110, and the reflective layer 130 (where first openings 131 reserved in the reflective layer 130 correspond to the light-emitting devices 120) is formed by using a printing process. Therefore, the reflective layer 130 is formed after a die bonding process (which refers to an operation of fixing the light-emitting devices 120 to the substrate 110), which may prevent precipitates of the reflective material during the curing process from adhering to the pads, prevent the precipitates from covering the surfaces of the pads, and in turn avoid affecting the soldering effect between the pads and the light-emitting devices. As a result, the probability of poor soldering caused by the precipitates of the reflective material during the curing process is reduced to 0%, which effectively improves the yield of the die bonding of the light-emitting substrate 10. By using the above method for manufacturing the light-emitting substrate 10, it may be possible to avoid the risk of reducing the reflectivity of the reflective layer 130 due to the reflow soldering process in the die bonding process, and in turn improve the luminance efficiency of the light-emitting substrate 10. As a result, the display brightness of the backlight module and the display apparatus 1 is improved, and the power consumption of the backlight module and the display apparatus 1 is reduced.

In addition, the reflective layer 130 is formed after the die bonding, which eliminates the impact of the step difference between the reflective layer 130 and the substrate on the die bonding. Multiple light-emitting devices 120 may be fixed simultaneously in each die bonding operation, thus improving the efficiency of the die bonding, saving the cost of the die bonding, reducing errors in the relative displacement between the light-emitting device and the first opening, improving the uniformity of the arrangement of the light-emitting devices, and in turn improving the uniformity of the light emitted from the light-emitting substrate.

In addition, after the first encapsulation structures 150 are formed, the plurality of dam structures 140 are formed on the reflective layer 130. The overlapping region of the dam structure 140 and the first encapsulation structure 150 in the direction perpendicular to the substrate may be used to consolidate the encapsulation effect of the first encapsulation structure 150, and the dam structure 140 is used to block the intrusion of water and oxygen into the light-emitting device and signal line(s) inside the first encapsulation structure to a certain extent, thereby increasing the anti-water and anti-oxygen distance of the light-emitting substrate. Therefore, it may improve the anti-water and anti-oxygen ability of the light-emitting substrate 10, enhance the corrosion resistance of the light-emitting device and the signal line, and improve the luminance lifetime of the light-emitting device 120 and the light-emitting substrate 10.

It can be understood that the plurality of dam structures 140 formed in the above method may be independent of each other and not connected to each other, or may be connected to each other and form a one-piece structure.

In some examples, when the plurality of dam structures 140 may be independent of each other and not connected to each other, the method of forming the plurality of dam structures 140 on the reflective layer 130 includes: forming a dam structure surrounding a light-emitting device 120 and on the reflective layer 130 by using a printing process or a coating process.

In this way, the dimensional accuracy and shape accuracy of each dam structure 140 may be improved.

In some other examples, when the plurality of dam structures 140 are connected to each other to constitute a grid-like structure, the method of forming the plurality of dam structures 140 on the reflective layer 130 includes S501 and S502.

In S501, as shown in FIG. 18, first sub-portions 144 are formed on two sides of each row of the plurality of rows of light-emitting devices 120 in the second direction and on the reflective layer 130 using a printing process or a coating process. The first sub-portions 144 extend in the first direction X.

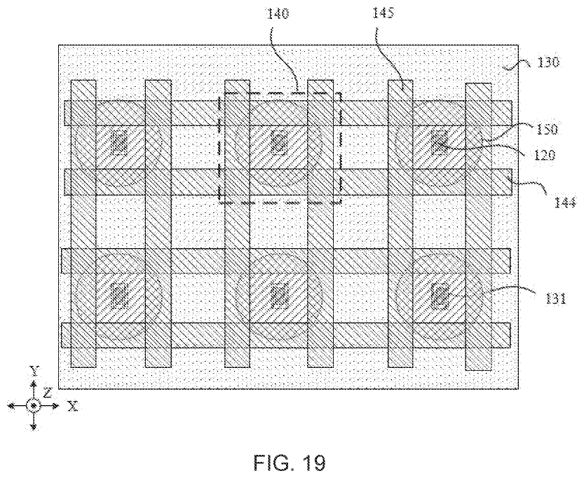

In S502, as shown in FIG. 19, second sub-portions 145 are formed on two sides of each column of the plurality of columns of light-emitting devices 120 in the first direction and on the reflective layer 130 using a printing process or a coating process. The second sub-portions 145 extend in the second direction. A second sub-portion 145 intersects the plurality of first sub-portions 144. Parts of two first sub-portions 144 and parts of two second sub-portions 145 surrounding the same light-emitting device 120 constitute a dam structure 140. Each dam structure 140 has a second opening 141, and an orthogonal projection of a first opening 131 on the substrate 110 is located within an orthogonal projection of a second opening 141 on the substrate 110. The orthogonal projection of a second opening 141 on the substrate 110 is located within an orthographic projection of a first encapsulation structure 150 on the substrate 110.

For example, the plurality of first sub-portions 144 and the plurality of second sub-portions 145 intersect with each other to form a structure in a shape of a Chinese character “#” or a mesh.

In this way, it is conducive to simplifying the manufacturing process of the dam structures 140.

In some examples, before fixing the plurality of light-emitting devices 120 to the first surface, the above manufacturing method further includes S110.

In S110, a cleaning process is performed on the first surface.

For example, a plasma surface treatment (Plasma) is used to clean the first surface and change the surface tension coefficient of a portion of the substrate 110 located around the light-emitting device 120, so that the surface tension coefficient is increased from less than 30 to about 40 to 60, which improves the wetting effect of the material of the reflective layer on the substrate 110, which alleviates and ameliorates the repel phenomenon in the subsequent printing of the reflective material; in addition, the shape accuracy of the formed reflective layer 130 is improved, and the dimensional accuracy of the first opening 131 in the reflective layer 130 is improved, which causes a small opening area of the first opening 131. As a result, the proportion of the area occupied by the reflective layer 130 on the substrate 110 is improved, and the light-emitting brightness of the light-emitting substrate 10 is improved.

In some embodiments, before forming the plurality of dam structures 140 on the reflective layer 130, the manufacturing method further includes S410.

In S410, as shown in FIG. 14, a plurality of driver chips 160 are fixed to the first surface. A driver chip 160 is electrically connected to at least one light-emitting device 120, and the driver chip 160 is configured to drive the at least one light-emitting device 120 to emit light.

For example, the plurality of driver chips 160 are fixed to the substrate 110 around the light-emitting devices 120 electrically connected thereto.

For example, a reflow soldering process may be used to fix the plurality of driver chips 160 to the first surface.

In this way, it may be possible to prevent the precipitates of the material of the reflective layer during the curing process from adhering to the pads electrically connected to the driver chips 160, prevent the precipitates from covering the surfaces of the pads, and in turn avoid affecting the soldering effect between the pads and the driver chips 160. As a result, it may effectively improve the yield of fixing the driver chips 160, and improve the yield of the light-emitting substrate 10.

In some examples, in the above-mentioned S300, during the process of forming the reflective layer 130 on the first surface using a printing process, as shown in FIG. 15, the reflective layer 130 further covers the plurality of driver chips 160.

In this way, the reflective layer 130 can be used to protect the driver chips 160 to avoid damage to the driver chips 160 during subsequent preparation processes, thereby improving the yield of the light-emitting substrate 10.

In some embodiments, in the above S500, the method of forming the plurality of dam structures 140 on the reflective layer 130 further includes S510.

In S510, as shown in FIG. 17, a plurality of second encapsulation structures 170 are formed on the plurality of driver chips 160. An orthographic projection of a driver chip 160 on the substrate 110 is located within an orthographic projection of a second encapsulation structure 170 on the substrate 110.

For example, the second encapsulation structures 170 may be made of white glue.

For example, the plurality of second encapsulation structures 170 are formed by using a coating process or a printing process.

For example, the second encapsulation structures 170 and the dam structures 140 in the above S500 are formed by a single patterning process, which may simplify the process flow of the light-emitting substrate 10.

In this way, the driver chips 160 may be further protected by the second encapsulation structures 170, and the luminance efficiency of the light-emitting substrate 10 may be improved, which avoids the driver chips 160 being exposed by the reflective layer due to the thickness of the reflective layer 130 being insufficient to cover the driver chips 160, and in turn avoid the light loss caused by the light emitted by the light-emitting devices 120 being incident on the driver chips 160 and not being reflected.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A light-emitting substrate, comprising:
a substrate having a first surface;
a plurality of light-emitting devices located on the first surface;
a reflective layer located on the first surface, wherein the reflective layer has a plurality of first openings, and a light-emitting device of the plurality of light-emitting devices is located in a first opening of the plurality of first openings;
a plurality of dam structures located on the reflective layer, wherein each dam structure of the plurality of dam structures has a second opening, and an orthogonal projection of the first opening on the substrate is located within an orthogonal projection of the second opening on the substrate; and
a plurality of first encapsulation structures located on a side of the plurality of light-emitting devices away from the substrate, wherein a first encapsulation structure of the plurality of first encapsulation structures covers at least one light-emitting device, and the orthogonal projection of the second opening on the substrate is located within an orthographic projection of the first encapsulation structure on the substrate.

2. The light-emitting substrate according to claim 1, wherein the dam structure has an inner side wall close to the first opening; and
the inner side wall of the dam structure and a side wall of the first opening have a distance therebetween.

3. The light-emitting substrate according to claim 1, wherein an orthographic projection of the dam structure on the substrate and the orthographic projection of the first encapsulation structure on the substrate have an overlapping region.

4. The light-emitting substrate according to claim 3, wherein the overlapping region is an annular pattern, and a radial size of the annular pattern is in a range of 0.05 mm to 0.1 mm.

5. The light-emitting substrate according to claim 1, wherein a ratio γ of a size of the second opening to a size of the first encapsulation structure satisfies: 0.92≤γ≤0.96.

6. The light-emitting substrate according to claim 1, wherein a shape of an orthographic projection of the dam structure on the substrate is annular;
the annular shape includes an inner contour and an outer contour; the inner contour is closer to the light-emitting device than the outer contour; and the inner contour constitutes a boundary of the orthogonal projection of the second opening on the substrate.

7. The light-emitting substrate according to claim 6, wherein a distance between the inner contour and the outer contour is in a range of 1.0 mm to 1.2 mm; and/or
a shape of the outer contour is a central symmetric pattern or an axial symmetric pattern.

8. The light-emitting substrate according to claim 6, wherein the outer contour is in a shape of a rectangle or a rounded rectangle.

9. The light-emitting substrate according to claim 1, wherein at least two of the plurality of dam structures are connected to each other to form a one-piece structure.

10. The light-emitting substrate according to claim 9, wherein the plurality of dam structures are connected to each other to form a grid-like structure; and the second opening is a square of the grid-like structure.

11. The light-emitting substrate according to claim 1, wherein a thickness of the dam structure is in a range of 0.03 mm to 0.05 mm; or
a material of the dam structure includes white glue, and a reflectivity of the dam structure is greater than or equal to 90%.

12. The light-emitting substrate according to claim 1, wherein a distance between the first opening and the light-emitting device located in the first opening is in a range of 0.1 mm to 0.2 mm.

13. The light-emitting substrate according to claim 1, further comprising: a plurality of driver chips located on the first surface, wherein a driver chip of the plurality of driver chips is electrically connected to at least one light-emitting device, and the driver chip is configured to drive the at least one light-emitting device to emit light; and
the reflective layer covers the plurality of driver chips.

14. The light-emitting substrate according to claim 13, further comprising a plurality of second encapsulation structures, wherein an orthographic projection of the driver chip on the substrate is located within an orthographic projection of a second encapsulation structure of the plurality of second encapsulation structures on the substrate.

15. The light-emitting substrate according to claim 14, wherein the plurality of second encapsulation structures and the plurality of dam structures are arranged in the same layer and made of the same material.

16. A manufacturing method of a light-emitting substrate, the manufacturing method comprising:
providing a substrate, the substrate having a first surface;
fixing a plurality of light-emitting devices to the first surface;
forming a reflective layer on the first surface, wherein the reflective layer has a plurality of first openings, and a light-emitting device of the plurality of light-emitting devices is located in a first opening of the plurality of first openings;
forming a plurality of first encapsulation structures on the plurality of light-emitting devices, a first encapsulation structure of the plurality of first encapsulation structures covering at least one light-emitting device; and
forming a plurality of dam structures on the reflective layer, wherein each dam structure of the plurality of dam structures has a second opening, and an orthogonal projection of the first opening on the substrate is located within an orthogonal projection of the second opening on the substrate; and the orthogonal projection of the second opening on the substrate is located within an orthographic projection of the first encapsulation structure on the substrate.

17. The manufacturing method according to claim 16, wherein before forming the plurality of dam structures on the reflective layer, the manufacturing method further comprises:
fixing a plurality of driver chips to the first surface, wherein a driver chip of the plurality of driver chips is electrically connected to at least one light-emitting device, and the driver chip is configured to drive the at least one light-emitting device to emit light; and
during a process of forming the reflective layer on the first surface using a printing process, the reflective layer further covers the plurality of driver chips.

18. The manufacturing method according to claim 17, further comprising:
forming a plurality of second encapsulation structures on the plurality of driver chips, an orthographic projection of the driver chip on the substrate being located within an orthographic projection of a second encapsulation structure on the substrate.

19. A backlight module, comprising:
the light-emitting substrate according to claim 1; and
an optical film located on a light exit side of the light-emitting substrate.

20. A display apparatus, comprising:
the backlight module according to claim 19;
a color filter substrate located on a light exit side of the backlight module; and
an array substrate located between the backlight module and the color filter substrate.
